(19) United States
(12) Patent Application Publication
(10) Pub. No.: US 2011/0079848 A1
(43) Pub. Date: Apr. 7, 2011

(54) SEMICONDUCTOR DEVICE WITH DUMMY GATE ELECTRODE AND CORRESPONDING INTEGRATED CIRCUIT AND MANUFACTURING METHOD

(75) Inventors: Jan Sonsky, Leuven (BE); Almudena Huerta, Madrid (ES)

(73) Assignee: NXP B.V., Eindhoven (NL)

(21) Appl. No.: 12/995,111

(22) PCT Filed: May 20, 2009
(86) PCT No.: PCT/IB09/52128

§ 371 Date: Dec. 1, 2010

(30) Foreign Application Priority Data
May 28, 2008 (EP) 08104129.5
May 20, 2009 (IB) PCT/IB2009/052128

(51) Int. Cl. H01L 29/78; H01L 21/336

(52) U.S. Cl. 257/337; 257/343; 438/197; 257/E29.255; 257/E21.409

(57) ABSTRACT

A field effect transistor semiconductor device configuration is described, which is particularly suitable for use in DC: DC converters associated with logic circuitry. The device includes a first gate electrode (18) which extends adjacent to its channel-accommodating region (14) and a second, dummy gate electrode (30) which extends adjacent to the drain drift region (12). The second gate electrode is electrically connected to the first gate electrode and serves to reduce the on-resistance of the device and improve its reliability by reducing hot carrier degradation.

The present invention relates to insulated gate field effect transistors (commonly termed “MOSFETs”) and the manufacture thereof. More particularly, it concerns reduction of the on-resistance of such devices and increasing their reliability.

MOSFETs are often employed in DC:DC converters within power management units (“PMUs”) associated with logic circuitry. The DC:DC converters facilitate the provision of multiple power supplies from a single power source connected to the PMU. It is desirable for the on-resistance of the MOSFET to be as low as possible to minimize power dissipation in the DC:DC converters and to allow the size of the MOSFETs to be reduced.

During the operation of known devices, high gate-source and drain-source voltages occur during transitions between the on and off states. This has been found to induce hot carrier degradation. These hot carriers may escape from the semiconductor body and get trapped in the gate oxide. Also, it has been observed that they experience a high electric field in the drift region (because of the high voltage of the drain) and are able to tunnel through the interface with the oxide on top of the drift region and get trapped above it. This latter degradation mechanism has been found to be the primary contributor to degradation by hot carrier injection in existing devices. This is because the quality of the interface with the gate oxide (formed thermally) is very high, but the interface quality with the deposited oxide on top of the drift region is poor. In order to improve the reliability of devices, it would be advantageous to suppress this degradation mechanism.

The present invention provides a semiconductor device including:

a semiconductor body, the semiconductor body comprising source and drain regions of a first conductivity type, and a channel-accommodating region of a second, opposite conductivity type which separates the source and drain regions, wherein the drain region comprises a drain contact region and a drain drift region, with the drain drift region between the channel-accommodating region and the drain contact region, and the drain drift region doped to a lesser extent than the drain contact region, the device further including a first gate electrode which extends adjacent to the channel-accommodating region, and a second gate electrode which extends adjacent to the drain drift region and is electrically connected to the first gate electrode.

The application of a voltage signal to the first gate electrode in the on-state of the device serves in a known manner to induce a conduction channel in the channel-accommodating region and to control current flow in this channel between the source and drain regions. The voltage at the second gate electrode is the same as that of the first gate electrode. With the second gate electrode at a positive potential, an accumulation layer of electrons forms in the drain drift region which has been found to greatly improve the on-resistance of the device. In addition, the presence of the second gate electrode has the effect of moving the electric field peak away from the edge of the first gate electrode, avoiding degradation of the gate oxide and therefore improving the reliability of the device.

In a preferred embodiment, the device is a lateral device (as opposed to a vertical configuration), in which the source, drain and channel-accommodating regions extend to a top major surface of the semiconductor body, and the first and second gate electrodes extend over the top major surface. This configuration may be fully compatible with CMOS logic processing. The oxide layer under the second gate electrode is a high quality thermal oxide without changing any process steps in the CMOS logic processing scheme. Therefore, the interface quality is improved, further reducing the risk of degradation by hot carrier injection.

Preferably, the second gate electrode is alongside and non-overlapping with the first gate electrode. The second gate electrode may extend adjacent to around 30-40% of the length of the drain drift region, measured in the direction from the channel-accommodating region to the drain contact region. It may for example be substantially the same size and shape as the first gate electrode in the active area of the device. Preferably, the second gate electrode is formed concurrently with the first gate electrode in the same processing steps, avoiding the need for any additional masks.

A known device and embodiment of the invention will now be described by way of example and with reference to the accompanying schematic drawings, wherein:

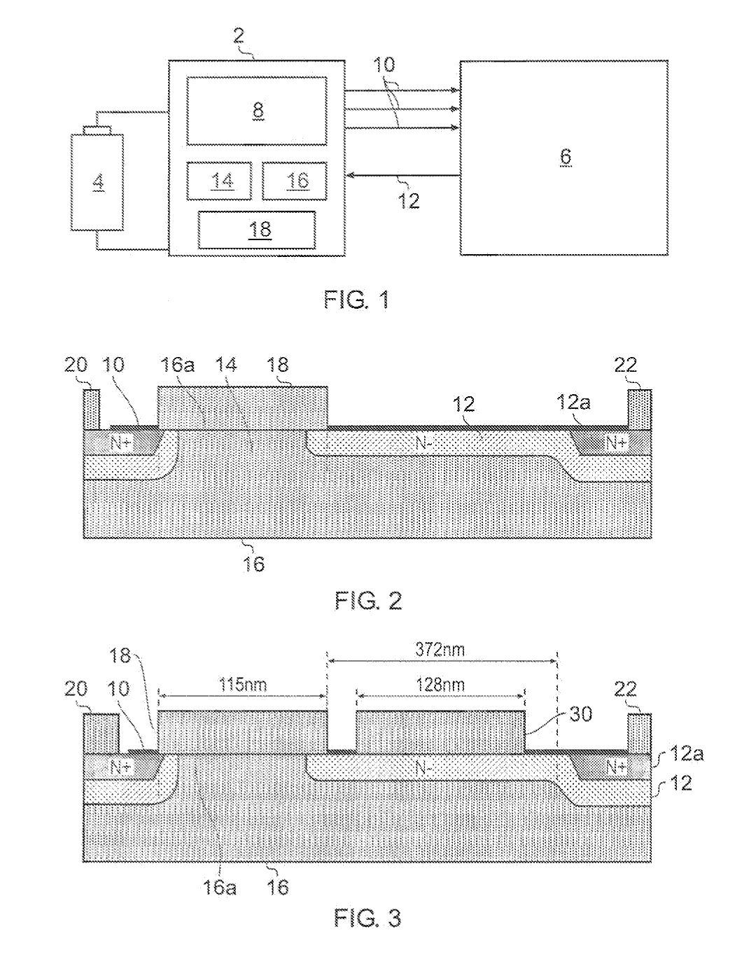

FIG. 1 shows a block diagram of a known PMU, in combination with a battery and logic circuitry;

FIG. 2 shows a cross-sectional side view of the known semiconductor device;

FIG. 3 shows a cross-sectional side view of a semiconductor device embodying the invention;

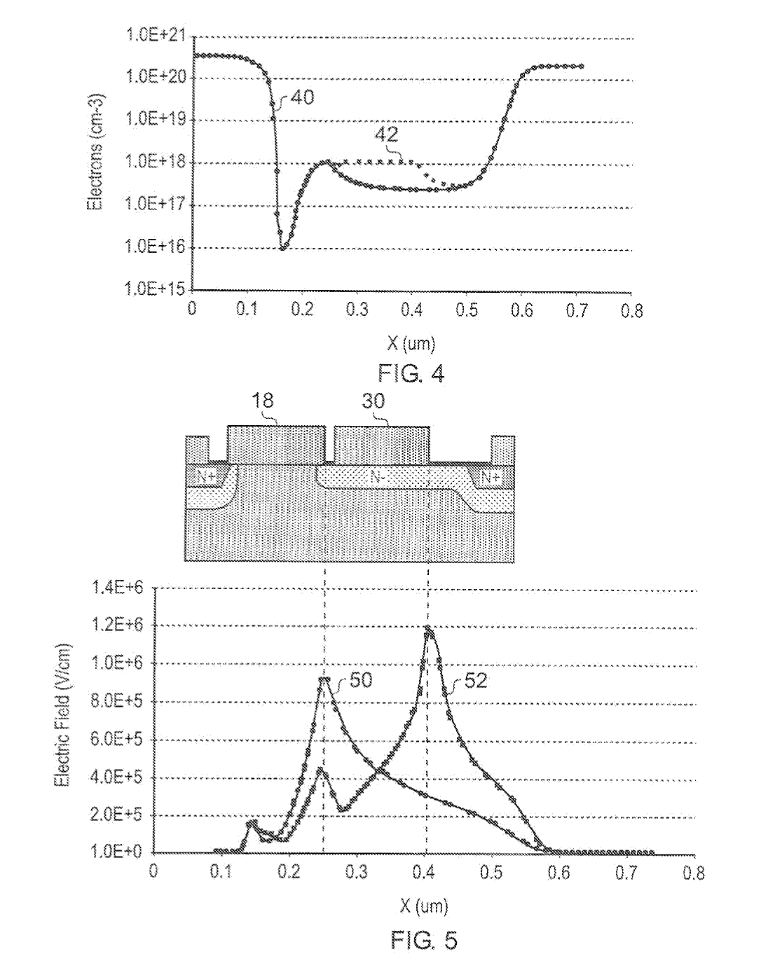

FIG. 4 is a graph generated by simulating devices of the form shown in FIGS. 2 and 3 and representing the current distribution; and

FIG. 5 is a graph generated by simulation of devices of the form shown in FIGS. 2 and 3, representing the electric field distribution in each device.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar features in modified and different embodiments.

FIG. 1 shows a block diagram of a known PMU 2, in combination with a battery 4 and logic circuitry 6. The PMU fulfils a number of functions. It manages and converts the battery voltage into supplies required by the logic circuitry using regulators and/or converters 8, to provide voltage supplies along the lines 10. The logic circuitry communicates with the PMU along line 12. The PMU may also include an on-off control block 14 to control the stand-by and power functions of the device, a control interface 16 to permit communication with the outside world, and other functionality in peripherals block 18.

Full integration of the PMU with the logic circuitry is beneficial as it affords an overall reduction in chip size, reduction of response time due to direct communication between the PMU and the logic circuitry, and reduction of the output voltage drop as a result of reduction of series resistances.

A schematic cross-sectional view of a known MOSFET device for use in a DC:DC converter as described above is shown in FIG. 2. It includes source and drain regions 10 and 12, 12a, respectively, of a first conductivity type (n-type in this example) which are separated by a channel-accommodating body region 14 of the opposite, second conductivity type (that is, p-type in this example). The device is formed in a p-type substrate 16 which provides the semiconductor body of the device.

The drain region comprises a low doped drift region 12 adjacent a more highly doped contact region 12a.

A gate electrode 18 is provided over a top major surface 16a of the semiconductor body and extends from over source region 10, across the channel-accommodating region 14, to over the drain drift region 12. The gate electrode is separated from the top major surface 16a by a layer of thermal silicon dioxide having a thickness of around 1 to l0 nm.

Source region 10 is contacted by a source electrode 20 at the top major surface 16a of the semiconductor body. The drain contact region 12a is contacted at the same surface by a drain electrode 22. The device configuration illustrated in FIG. 2 may be manufactured using well known semiconductor device fabrication techniques familiar to the skilled reader such as photolithography, etching and implantation.

The breakdown voltage typically required for the MOSFETs of the DC:DC converters or voltage regulators is of the order of 5 to 30V.

A modified version of the device shown in FIG. 2 which embodies the present invention is shown in FIG. 3. A second gate electrode or dummy gate 30 is provided over the drain drift region 12 only in the active area of the device, alongside gate 18. The second gate electrode is electrically connected to the first gate electrode 18 so that they are both held at the same potential.

The length of the first gate electrode measured in the direction from the source to the drain region may be around 60 to 500 nm. The length of the second gate electrode may be around 100 nm, for example, when provided over a drain drift region around 300 nm long.

Provision of the second gate electrode has been found to significantly reduce the on-resistance of the device, giving a reduction of nearly 40%.

FIG. 4 is a graph showing a simulation of the current density distribution in devices having the configurations shown in FIG. 2 and FIG. 3. The electron density at the surface of the device is plotted with respect to the x direction, measured from the source region towards the drain region. Line 40 corresponds to the known device configuration of FIG. 2, whilst dashed line 42 indicates where this curve is deviated from by the device embodying the invention having the configuration shown in FIG. 3. This illustrates the formation of an accumulation layer of electrons at the surface of the drift region beneath the second gate electrode.

FIG. 5 represents a graph generated by simulation of the electric field distribution in devices having the configurations shown in FIGS. 2 and 3. Plot 50 corresponds to the known FIG. 2 configuration whilst plot 52 corresponds to the device embodying the invention as depicted in FIG. 3. It can be seen that in the device embodying the invention, the maximum electric field peak is displaced to the edge of the second gate electrode 30, away from first gate electrode 18.

Preferably, second gate electrode 30 is formed concurrently with the first gate electrode 18 by the same processing steps, allowing accurate control of their relative sizes and positions. The thickness of the layer of insulating material (preferably silicon dioxide) beneath the first and second gates may be substantially the same. It may be around 1 to l0 nm thick, for example.

From reading the present disclosure, other variations and modifications will be apparent to persons skilled in the art. Such variations and modifications may involve equivalent and other features which are already known in the art, and which may be used instead of or in addition to features already described herein.

Although claims have been formulated in this application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicants hereby give notice that new claims may be formulated to such features and/or combinations of such features during the prosecution of the present application or of any further application derived therefrom.

1. A semiconductor device including a semiconductor body, the semiconductor body comprising source and drain regions of a first conductivity type, and a channel-accommodating region of a second, opposite conductivity type which separates the source and drain regions, wherein the drain region comprises a drain contact region and a drain drift region, with the drain drift region between the channel-accommodating region and the drain contact region, and the drain drift region doped to a lesser extent than the drain contact region, the device further including a first gate electrode which extends adjacent to the channel-accommodating region, and a second gate electrode which extends adjacent to the drain drift region and is electrically connected to the first gate electrode.

2. A device of claim 1 wherein the device is a lateral device, in which the source, drain and channel-accommodating regions extend to a top major surface of the semiconductor body, and the first and second gate electrodes extend over the top major surface.

3. A device of claim 2 wherein the second gate electrode is non-overlapping with the first gate electrode.

4. A device of claim 1 wherein the second gate electrode is spaced from the first gate electrode in the direction from the channel-accommodating region to the drain contact region in the active area of the device.

5. A device of claim 1 wherein the second gate electrode extends adjacent to about 30 to about 40% of the length of the drain drift region, measured in the direction from the channel-accommodating region to the drain contact region.

6. A device of claim 1 wherein the second gate electrode is substantially the same size and shape as the first gate electrode in the active area of the device.

7. An integrated circuit including a device of claim 1.

8. A method of manufacturing a device of claim 1.

9. A method of manufacturing an integrated circuit, as recited in claim 7.
